(19) United States
(12) Patent Application Publication
(10) Pub. No.: US 2026/0190453 A1
(43) Pub. Date: Jul. 2, 2026

(54) SEMICONDUCTOR DEVICE AND POWER MODULE

(71) Applicant: Mitsubishi Electric Corporation, Tokyo (JP)

(72) Inventors: Kazuki NISHIDA, Tokyo (JP); Kazuya KONISHI, Tokyo (JP); Kosuke SAKAGUCHI, Tokyo (JP); Tomokazu KANNA, Tokyo (JP); Koji TANAKA, Tokyo (JP)

(73) Assignee: Mitsubishi Electric Corporation, Tokyo (JP)

(21) Appl. No.: 19/415,458

(22) Filed: Dec. 10, 2025

(30) Foreign Application Priority Data
Dec. 26, 2024 (JP) 2024-230269

(51) Int. Cl. H10D 84/00; H10D 12/00; H10D 30/66; H10D 62/10; H10D 62/60; H10D 64/23; H10D 64/27

(52) U.S. Cl. CPC H10D 84/161; H10D 12/481; H10D 30/668; H10D 62/103; H10D 62/124; H10D 62/60; H10D 64/232; H10D 64/518

(57) ABSTRACT

An object of the present disclosure is to provide a semiconductor device capable of improving withstand voltage. A semiconductor device according to the present disclosure includes: a semiconductor substrate; a base layer provided to a side of an upper surface of the semiconductor substrate; at least one carrier accumulation layer provided below the base layer; and at least one two-stage trench having an upper electrode and a lower electrode in an upper tier and a lower tier, respectively, inside a trench provided to the side of the upper surface of the semiconductor substrate to pass through the base layer and the carrier accumulation layer, wherein a lower end of the upper electrode is located more upward than a lower end of the carrier accumulation layer and more downward than a center position of the carrier accumulation layer in an up-down direction.

### BACKGROUND

### Technical Field

The present disclosure relates to a semiconductor device in which power conduction is controlled by a gate signal and a power module including the semiconductor device.

### Description of the Background Art

Conventionally disclosed is an insulated gate bipolar transistor (IGBT) including two-stage trench with an upper electrode and a lower electrode inside a trench and a carrier accumulation layer (for example, refer to Japanese Patent Application Laid-Open No. 2020-77727).

### SUMMARY

There are three high electrical field regions in the IGBT including the two-stage trench and the carrier accumulation layer. A first high electrical field region is a region between an interface between the carrier accumulation layer and a base layer and a center position of the carrier accumulation layer. In this region, electrical field gets high in a depletion layer region made up of a p-type semiconductor layer and an n-type semiconductor layer.

A second high electrical field region is a region on a lower side of the carrier accumulation layer in which a hole is accumulated in a viewpoint of dynamic withstand voltage. When a gate is rapidly switched off in a turn-off operation, implantation of electrons from a channel decreases, and in the region on the lower side of the carrier accumulation layer, positive charge holes are accumulated in the carrier accumulation layer more than negative charge electrons. Thus, there is a possibility that electrical field gets high due to increase of space charge.

A third high electrical field region is located in a corner part of a lower end of the upper electrode. The electrical field is concentrated in the corner part and gets high. The third high electrical field region is a region specific to the IGBT including the two-stage trench.

The inventors found a problem specific to the IGBT including the two-stage trench and the carrier accumulation layer that when the third high electrical field region is overlapped with the first high electrical field region or the second high electrical field region, the electrical field is amplified and withstand voltage decreases.

An object of the present disclosure is to provide a semiconductor device capable of improving withstand voltage.

A semiconductor device according to the present disclosure includes: a semiconductor substrate; a base layer provided to a side of an upper surface of the semiconductor substrate; at least one carrier accumulation layer provided below the base layer; and at least one two-stage trench having an upper electrode and a lower electrode in an upper tier and a lower tier, respectively, inside a trench provided to the side of the upper surface of the semiconductor substrate to pass through the base layer and the carrier accumulation layer, wherein a lower end of the upper electrode is located more upward than a lower end of the carrier accumulation layer and more downward than a center position of the carrier accumulation layer in an up-down direction.

According to the present disclosure, withstand voltage can be improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to an embodiment 1.

FIG. 2 is a diagram for explaining a high electrical field region in the semiconductor device according to the embodiment 1.

FIG. 3 is a diagram illustrating a relationship between an up-down direction of an upper electrode, withstand voltage, and an impurity concentration in the semiconductor device according to the embodiment 1.

FIG. 4 is a diagram for explaining a high electrical field region in the semiconductor device.

FIG. 5 is a diagram for explaining a high electrical field region in the semiconductor device.

FIG. 6 is a cross-sectional view of a semiconductor device according to a modification example 1 of the embodiment 1.

FIG. 7 is a cross-sectional view of a semiconductor device according to a modification example 2 of the embodiment 1.

FIG. 8 is a cross-sectional view of a semiconductor device according to a modification example 3 of the embodiment 1.

FIG. 9 is a cross-sectional view of a semiconductor device according to a modification example 4 of the embodiment 1.

FIG. 10 is a cross-sectional view of a semiconductor device according to a modification example 5 of the embodiment 1.

FIG. 11 is a cross-sectional view of the semiconductor device according to the modification example 5 of the embodiment 1.

FIG. 12 is a cross-sectional view of a semiconductor device according to a modification example 6 of the embodiment 1.

FIG. 13 is a cross-sectional view of a semiconductor device according to a modification example 7 of the embodiment 1.

FIG. 14 is a cross-sectional view of a semiconductor device according to a modification example 8 of the embodiment 1.

FIG. 15 is a cross-sectional view of a semiconductor device according to a modification example 9 of the embodiment 1.

FIG. 16 is a cross-sectional view of a semiconductor device according to a modification example 10 of the embodiment 1.

FIG. 17 is a cross-sectional view of a semiconductor device according to a modification example 11 of the embodiment 1.

FIG. 18 is a cross-sectional view of a semiconductor device according to a modification example 12 of the embodiment 1.

FIG. 19 is a diagram illustrating an impurity concentration of each layer in a semiconductor device according to a modification example 13 of the embodiment 1.

FIG. 20 is a diagram illustrating an impurity concentration of each layer in the semiconductor device according to the modification example 13 of the embodiment 1.

FIG. 21 is a cross-sectional view of a semiconductor device according to a modification example 15 of the embodiment 1.

FIG. 22 is a cross-sectional view of a semiconductor device according to a modification example 16 of the embodiment 1.

FIG. 23 is a cross-sectional view of a semiconductor device according to a modification example 17 of the embodiment 1.

FIG. 24 is a cross-sectional view of a semiconductor device according to a modification example 18 of the embodiment 1.

FIG. 25 is a cross-sectional view of a semiconductor device according to a modification example 19 of the embodiment 1.

FIG. 26 is a cross-sectional view of a semiconductor device according to a modification example 20 of the embodiment 1.

FIG. 27 is a cross-sectional view of a semiconductor device according to a modification example 21 of the embodiment 1.

FIG. 28 is a plan view of a power module according to an embodiment 2.

### DESCRIPTION OF THE PREFERRED EMBODIMENTS

### Embodiment 1

A semiconductor device according to an embodiment is described hereinafter with reference to the diagrams. The semiconductor device is an IGBT. The same signs are assigned to the same or corresponding constituent elements, and a repetitive description is omitted in some cases. In the description hereinafter, n and p indicate conductivity types of a semiconductor. These conductivity types may be reversed.

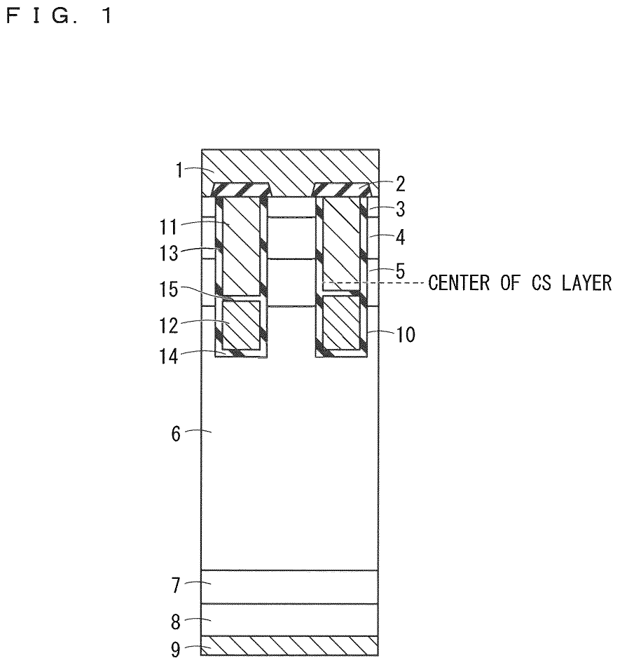

FIG. 1 is a cross-sectional view of the semiconductor device according to an embodiment 1. In FIG. 1, a semiconductor substrate ranges from a source layer 3 to a collector layer 8. In FIG. 1, an upper end of the source layer 3 is referred to as an upper surface of the semiconductor substrate, and a lower end of the collector layer 8 is referred to as a lower surface of the semiconductor substrate. The upper surface and the lower surface face each other.

As illustrated in FIG. 1, an n-type carrier accumulation layer 5 having a higher n-type impurity concentration than a drift layer 6 is provided to a side of an upper surface of the n-type drift layer 6. The carrier accumulation layer 5 is also referred to as “the CS layer” hereinafter.

The p-type base layer 4 is provided to a side of an upper surface of the carrier accumulation layer 5. The n-type source layer 3 is provided to a side of an upper surface of the base layer 4.

Provided to the semiconductor substrate is a two-stage trench 10 passing through the source layer 3, the base layer 4, and the carrier accumulation layer 5 to reach the drift layer 6. The two-stage trench 10 includes an upper electrode 11 and a lower electrode 12 in an upper tier and a lower tier, respectively, inside a trench provided to the side of the upper surface of the semiconductor substrate. The upper electrode 11 is covered by an upper insulating film 13, and the lower electrode 12 is covered by a lower insulating film 14. The two-stage trench 10 includes a boundary insulating film 15 between the upper electrode 11 and the lower electrode 12. The upper electrode 11 and the lower electrode 12 are electrically separated from each other via the boundary insulating film 15.

A lower end of the upper electrode 11 is located more upward than a lower end of the carrier accumulation layer 5 and more downward than a center position (“center of CS layer” illustrated in FIG. 1) of the carrier accumulation layer 5 in an up-down direction.

An interlayer insulating film 2 is provided on the two-stage trench 10. An emitter electrode 1 is provided on the source layer 3 and the interlayer insulating film 2.

An n-type buffer layer 7 having a higher n-type impurity concentration than the drift layer 6 is provided to a side of a lower surface of the drift layer 6. A p-type collector layer 8 is provided to a side of a lower surface of the buffer layer 7. A collector electrode 9 is provided to a side of a lower surface of the collector layer 8.

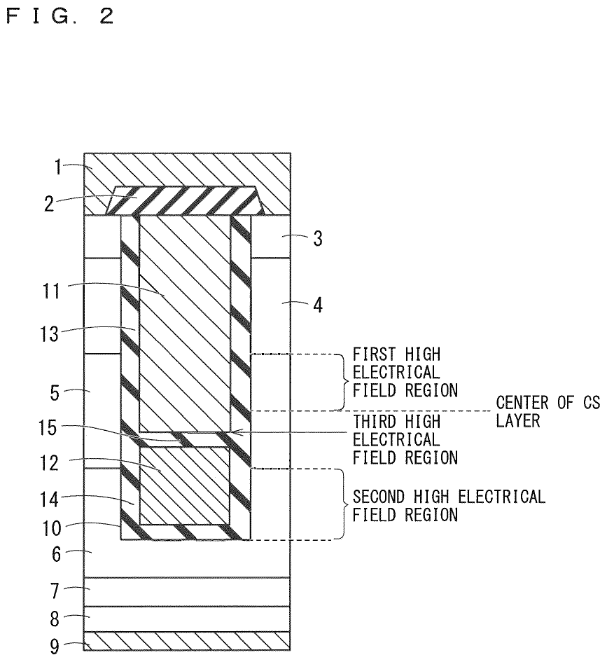

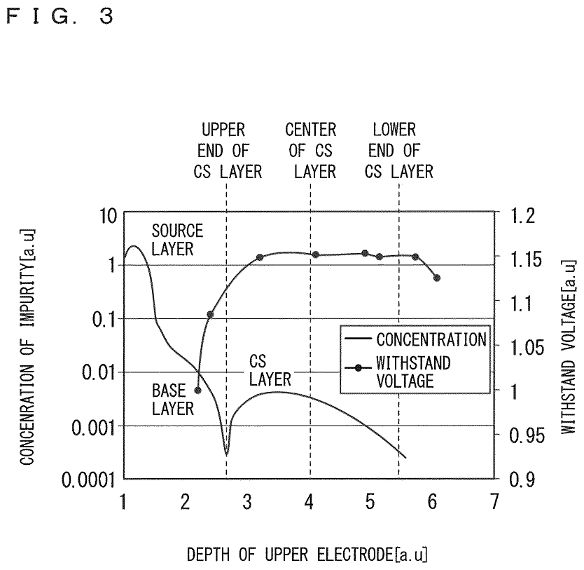

FIG. 2 is a diagram for explaining a high electrical field region in the semiconductor device according to the embodiment 1. As illustrated in FIG. 2, since the lower end of the upper electrode 11 is located more upward than the lower end of the carrier accumulation layer 5 and more downward than the center position (the center of the CS layer) of the carrier accumulation layer 5 in the up-down direction, the third high electrical field region is not overlapped with any of the first high electrical field region and the second high electrical field region. Accordingly, withstand voltage of the semiconductor device can be improved as illustrated in FIG. 3. FIG. 3 is a diagram illustrating a relationship between the up-down direction of the upper electrode 11, withstand voltage (collector-emitter withstand voltage), and the impurity concentration in the semiconductor device according to the embodiment 1. A hatching part illustrated in FIG. 3 indicates a range where the lower end of the upper electrode 11 is located. When the lower end of the upper electrode 11 is located within this range, the third electrical field region is not overlapped with any of the first high electrical field region and the second high electrical field region.

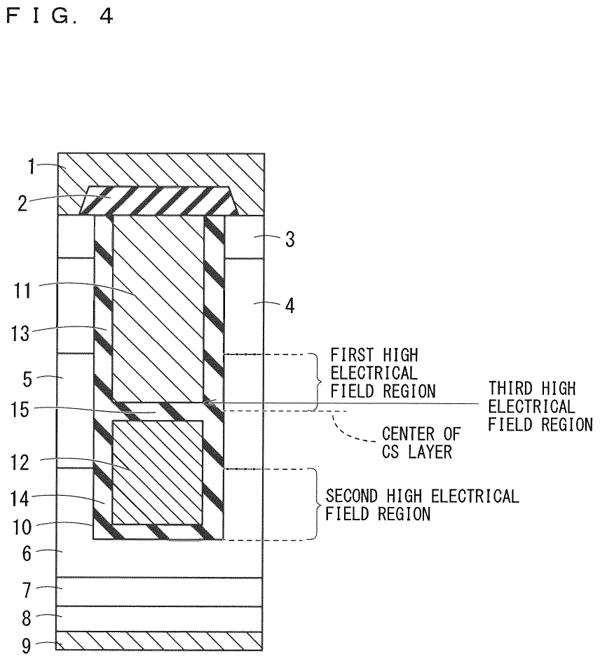

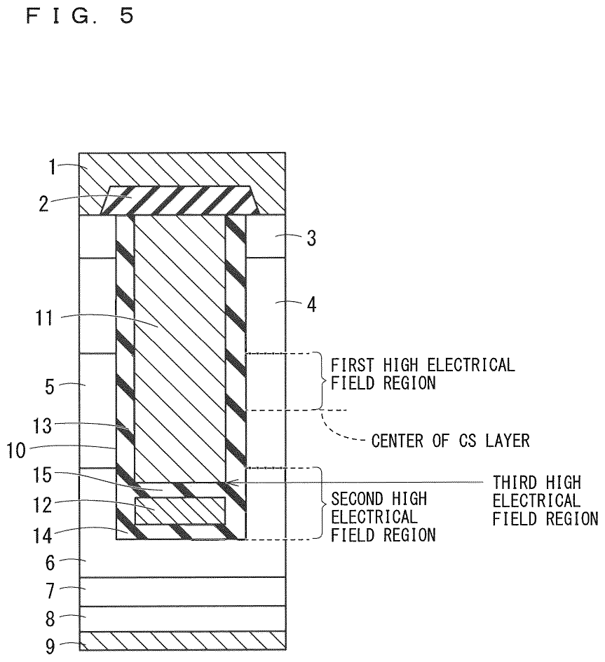

In the meanwhile, when the third high electrical field region and the first high electrical field region are overlapped with each other (refer to FIG. 4) or when the third high electrical field region and the second high electrical field region are overlapped with each other (refer to FIG. 5), withstand voltage of the semiconductor device decreases due to concentration of electrical field.

Although a lower end of the second high electrical field region is located to be aligned with a lower end of the two-stage trench 10 in FIGS. 2, 4, and 5, the configuration is not limited thereto. The lower end of the second high electrical field region may be located more upward or downward than the lower end of the two-stage trench 10.

According to the embodiment 1, the lower end of the upper electrode 11 is located more upward than the lower end of the carrier accumulation layer 5 and more downward than the center position of the carrier accumulation layer 5 in the up-down direction. Accordingly, withstand voltage (collector-emitter withstand voltage) of the semiconductor device can be improved.

Influence of the second high electrical field region caused by the hole is particularly large in an IGBT in which the hole is used as a carrier, and the withstand voltage of the semiconductor device as the IGBT according to the embodiment 1 can be further improved.

### Modification Example 1

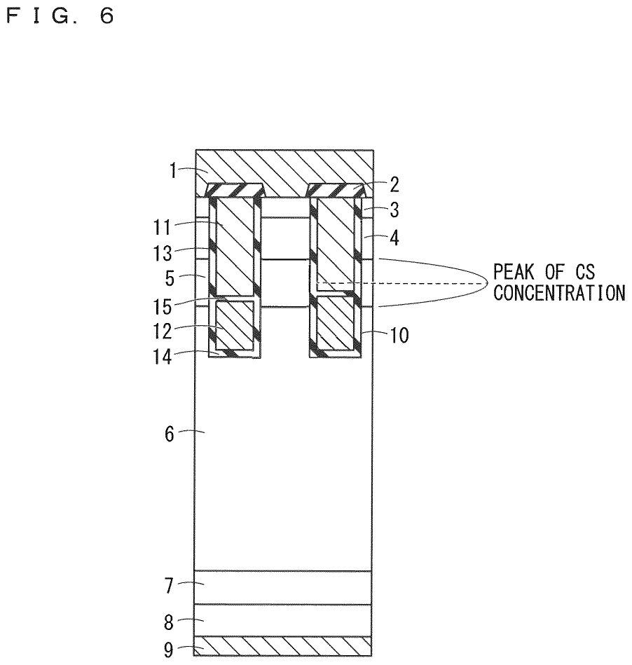

FIG. 6 is a cross-sectional view of a semiconductor device according to a modification example 1 of the embodiment 1. As illustrated in FIG. 6, a peak of the impurity concentration of the carrier accumulation layer 5 is located more downward than an upper end of the carrier accumulation layer 5. The lower end of the upper electrode 11 is located more downward than the peak of the impurity concentration of the carrier accumulation layer 5.

According to the modification example 1, since the lower end (the third high electrical field region) of the upper electrode 11 is located more downward than the peak of the impurity concentration of the carrier accumulation layer 5 in which many carriers are accumulated and the electrical field gets high, the withstand voltage of the semiconductor device can be improved.

### Modification Example 2

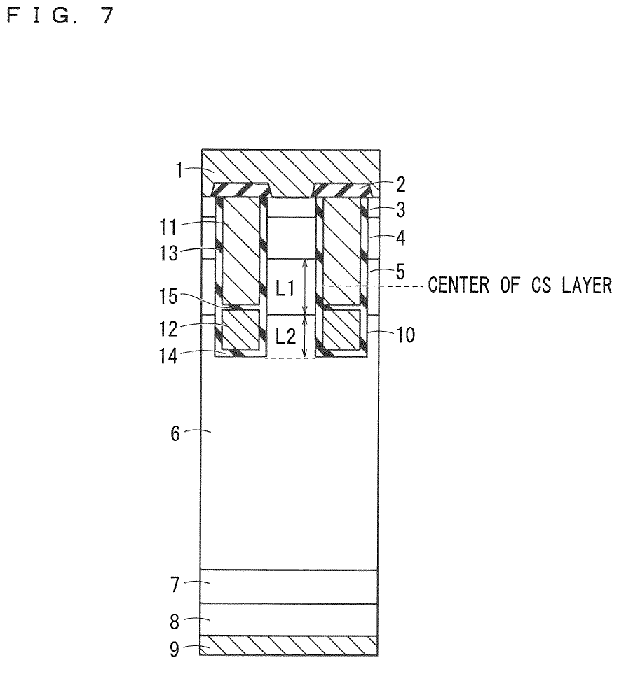

FIG. 7 is a cross-sectional view of a semiconductor device according to a modification example 2 of the embodiment 1. As illustrated in FIG. 7, a length L2 between the lower end of the carrier accumulation layer 5 and the lower end of the two-stage trench 10 is smaller than a length L1 of the carrier accumulation layer 5 in the up-down direction. L1 is preferable twice or more as large as L2.

According to the modification example 2, a hole density on the lower side of the two-stage trench 10 gets high by dynamic avalanche in a turn-off operation. Thus, electrical field strength can be reduced by bringing the lower end of the two-stage trench 10 close to the carrier accumulation layer 5 in which an electron density gets high.

### Modification Example 3

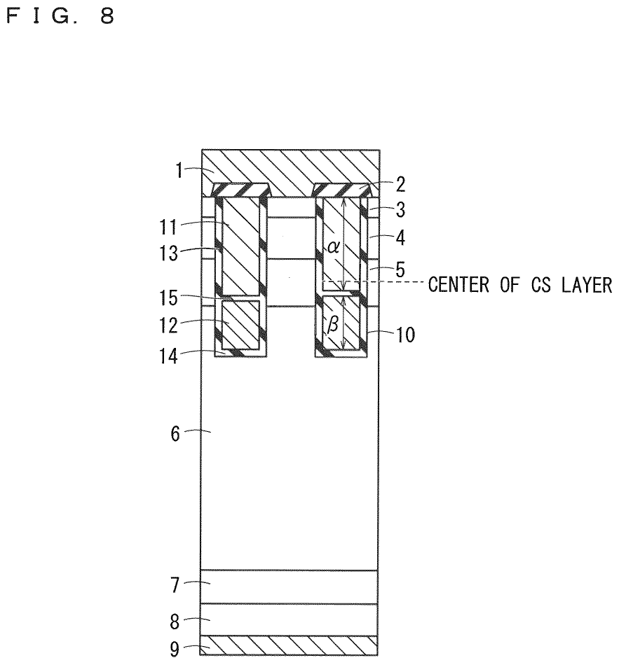

FIG. 8 is a cross-sectional view of a semiconductor device according to a modification example 3 of the embodiment 1. As illustrated in FIG. 8, a length β of the lower electrode 12 in the up-down direction is smaller than a length α of the upper electrode 11 in the up-down direction.

According to the modification example 3, a cross-sectional area of the upper electrode 11 contributing to a channel is increased; thus, gate wiring resistance can be reduced. Moreover, since a depth of the two-stage trench 10 (the length of the two-stage trench 10 in the up-down direction) is not large, the withstand voltage of the semiconductor device is not also reduced.

Since an N-layer region formed in a sidewall of the two-stage trench 10 increases, ON voltage of the semiconductor device can be reduced. The effect increases when this configuration is combined with a configuration of a semiconductor device according to a modification example 9 described hereinafter. The N-layer region is a region in which a reverse layer channel formed in a boundary part between the base layer 4 and the two-stage trench 10 by a minority carrier and a region (n-type accumulation layer) in which the carrier accumulation layer 5 faces the upper electrode 11 via the upper insulating film 13 are combined.

### Modification Example 4

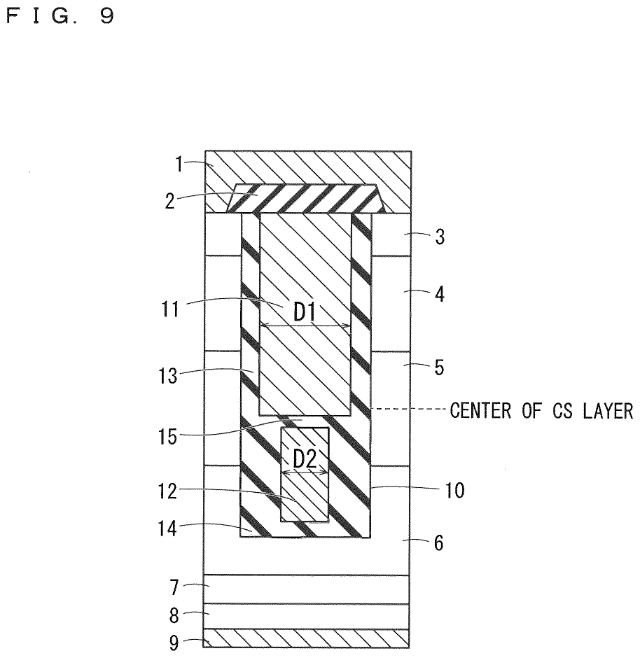

FIG. 9 is a cross-sectional view of a semiconductor device according to a modification example 4 of the embodiment 1. As illustrated in FIG. 9, a width D1 of the upper electrode 11 in a right-left direction is larger than a width D2 of the lower electrode 12 in the right-left direction. Herein, the right-left direction indicates a vertical direction with respect to the up-down direction of the semiconductor substrate.

Since the upper electrode 11 protrudes more than the lower electrode 12 in the right-left direction in a cross-sectional view, electrical field is concentrated more in a corner part of the lower end of the upper electrode 11, and withstand voltage of the semiconductor device is reduced.

According to the modification example 4, the lower end of the upper electrode 11 is located more upward than the lower end of the carrier accumulation layer 5 and more downward than the center position of the carrier accumulation layer 5 in the up-down direction. Thus, a higher electrical field reduction effect can be obtained, and withstand voltage of the semiconductor device can be improved.

### Modification Example 5

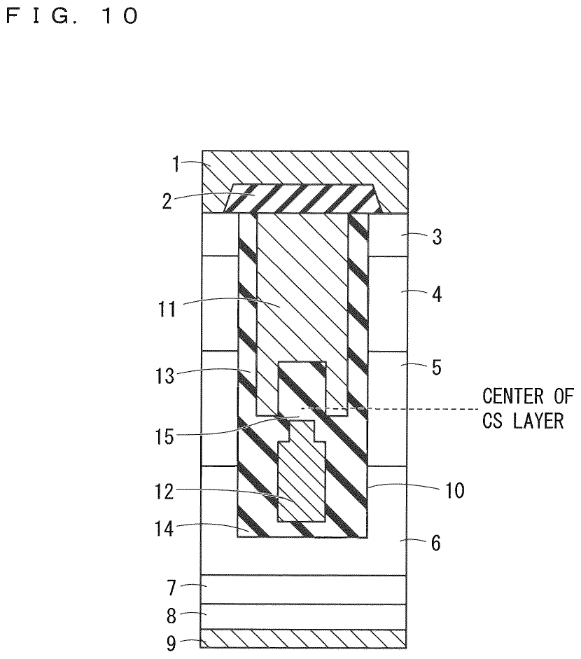

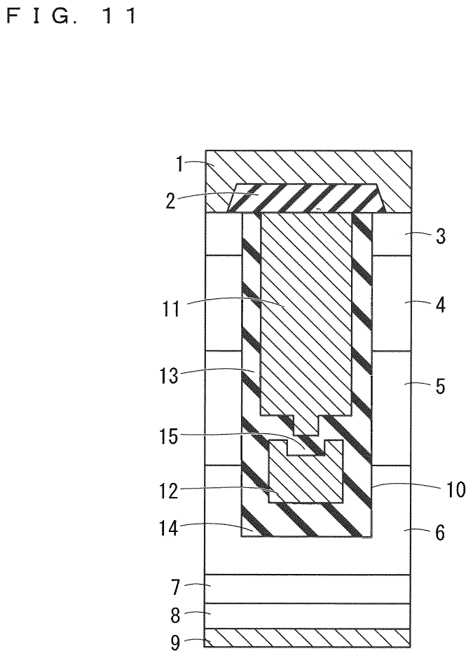

FIGS. 10 and 11 are cross-sectional views of a semiconductor device according to a modification example 5 of the embodiment 1. As illustrated in FIGS. 10 and 11, the upper electrode 11 includes a projection part on the lower end. In the example in FIG. 10, the upper electrode 11 includes a projection part in the corner part of the lower end. In the example in FIG. 11, the upper electrode 11 includes a projection part in a center part of the lower end.

When a film thickness of the lower insulating film 14 is larger than that of the upper insulating film 13, the projection part may be formed in the corner part of the lower end of the upper electrode 11 in some cases, and the electrical field is concentrated more in this projection part, and the withstand voltage of the semiconductor device decreases.

According to the modification example 5, the lower end of the upper electrode 11 is located more upward than the lower end of the carrier accumulation layer 5 and more downward than the center position of the carrier accumulation layer 5 in the up-down direction. Thus, a higher electrical field reduction effect can be obtained, and withstand voltage of the semiconductor device can be improved.

When the example in FIGS. 10 and 11 illustrates the case where the film thickness of the lower insulating film 14 is larger than that of the upper insulating film 13, the film thickness of the lower insulating film 14 may be the same as that of the upper insulating film 13.

### Modification Example 6

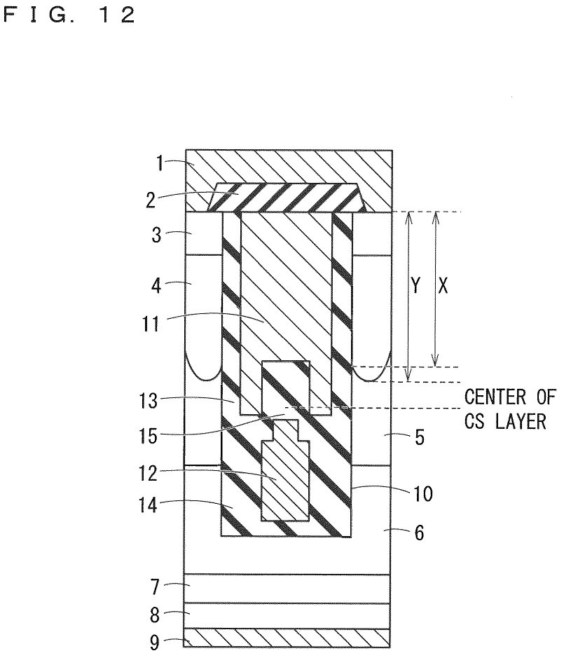

FIG. 12 is a cross-sectional view of a semiconductor device according to a modification example 6 of the embodiment 1. As illustrated in FIG. 12, a length x of the base layer 4 in the up-down direction at an interface with the two-stage trench 10 is smaller than a length y of the base layer 4 in the up-down direction at a center of a mesa part. The mesa part corresponds to a region between the two-stage trenches 10 adjacent to each other.

According to the modification example 6, a distance between the interface between the base layer 4 and the carrier accumulation layer 5 tending to have high electrical field and the corner part of the lower end of the upper electrode 11 can be increased. Thus, the high electrical field region is not overlapped, and the withstand voltage of the semiconductor device can be improved.

Although FIG. 12 illustrates the example that the upper electrode 11 includes the projection part, the configuration is not limited thereto. The configuration of the two-stage trench 10 may be the configuration of the two-stage trench 10 described in the modification examples 1 to 4.

### Modification Example 7

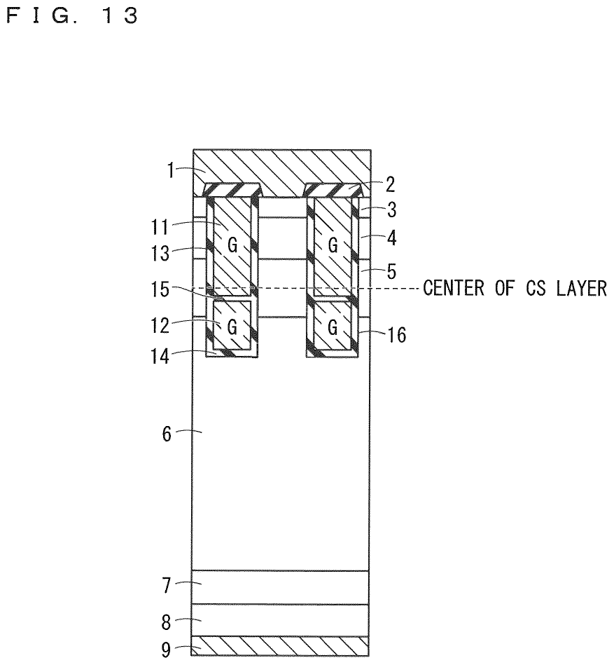

FIG. 13 is a cross-sectional view of a semiconductor device according to a modification example 7 of the embodiment 1. As illustrated in FIG. 13, the semiconductor device according to the modification example 7 includes a two-stage active trench 16 in which the upper electrode 11 and the lower electrode 12 are electrically connected to a gate electrode (not shown). That is to say, the two-stage trench 10 illustrated in FIG. 1 includes the two-stage active trench 16.

According to the modification example 7, the lower electrode 12 is electrically connected to the gate electrode; thus, the n-type accumulation layer can be formed in the trench interface around the lower electrode 12, and an electron implantation amount can be increased. Since the electron density in the turn-off operation can be increased and space charge can be reduced, and the electrical field of the second high electrical field region can be reduced. Thus, the withstand voltage of the semiconductor device can be improved.

The configuration of the two-stage active trench 16 illustrated in FIG. 13 may be applied to the configuration of the two-stage trench 10 described in the modification examples 1 to 6.

### Modification Example 8

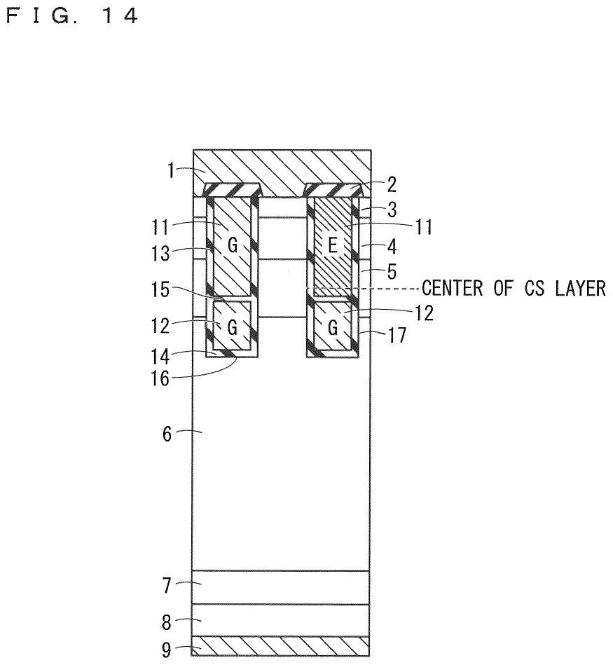

FIG. 14 is a cross-sectional view of a semiconductor device according to a modification example 8 of the embodiment 1. As illustrated in FIG. 14, the semiconductor device according to the modification example 8 includes a two-stage dummy active trench 17 in which the upper electrode 11 is electrically connected to the emitter electrode 1 and the lower electrode 12 is electrically connected to the gate electrode (not shown). That is to say, the two-stage trench 10 illustrated in FIG. 1 includes the two-stage dummy active trench 17.

According to the modification example 8, the lower electrode 12 is electrically connected to the gate electrode; thus, the n-type accumulation layer can be formed in the trench interface around the lower electrode 12, and an electron implantation amount can be increased. Since the electron density in the turn-off operation can be increased and space charge can be reduced, and the electrical field of the second high electrical field region can be reduced. Thus, the withstand voltage of the semiconductor device can be improved.

Since the upper electrode 11 is electrically connected to the emitter electrode 1, potential of the mesa part around the upper electrode 11 can be lowered compared with a case where the upper electrode 11 is electrically connected to the gate electrode. In this manner, since the potential of the mesa part around the upper electrode 11 can be reduced, the electrical field of the interface between the base layer 4 and the carrier accumulation layer 5 included in the first high electrical field region can be further reduced, and the withstand voltage of the semiconductor device can be improved.

The configuration of the two-stage dummy active trench 17 illustrated in FIG. 14 may be applied to the configuration of the two-stage trench 10 described in the modification examples 1 to 6. As illustrated in FIG. 14, the semiconductor device may include the two-stage dummy active trench 17 and the two-stage active trench 16 according to the modification example 7 in combination.

### Modification Example 9

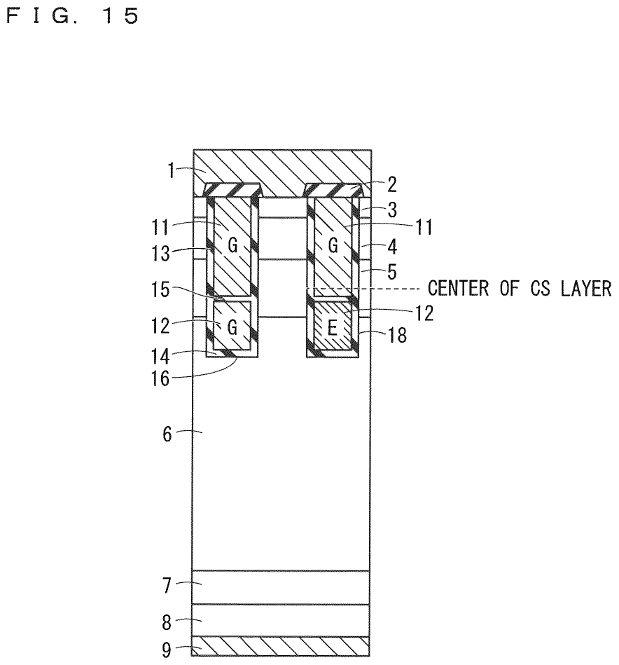

FIG. 15 is a cross-sectional view of a semiconductor device according to a modification example 9 of the embodiment 1. As illustrated in FIG. 15, the semiconductor device according to the modification example 9 includes a two-stage active dummy trench 18 in which the upper electrode 11 is electrically connected to the gate electrode (not shown) and the lower electrode 12 is electrically connected to the emitter electrode 1. That is to say, the two-stage trench 10 illustrated in FIG. 1 includes the two-stage active dummy trench 18.

According to the modification example 9, since the lower electrode 12 is electrically connected to the emitter electrode 1, the potential around the trench can be reduced. Thus, the electrical field can be reduced, and the withstand voltage of the semiconductor device can be improved.

When a feedback capacity is reduced, a negative capacity effect can be reduced. Thus, improvement of the withstand voltage of the semiconductor device can be expected while oscillation is avoided during a short-circuit power conduction.

The configuration of the two-stage active dummy trench 18 illustrated in FIG. 15 may be applied to the configuration of the two-stage trench 10 described in the modification examples 1 to 6. Although the semiconductor device illustrated in FIG. 15 includes the two-stage active dummy trench 18 and the two-stage active trench 16 according to the modification example 7 in combination, the configuration is not limited thereto. The semiconductor device may appropriately include the two-stage active dummy trench 18, the two-stage dummy active trench 17 according to the modification example 8, and the two-stage active trench 16 according to the modification example 7 in combination.

### Modification Example 10

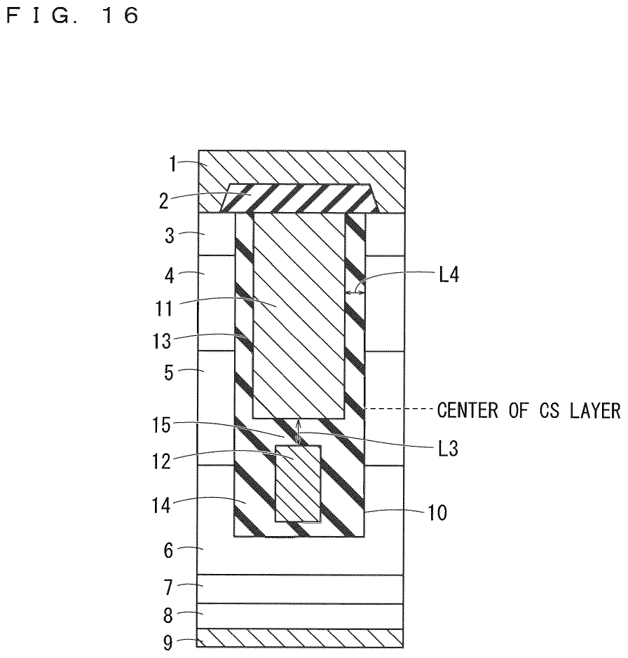

FIG. 16 is a cross-sectional view of a semiconductor device according to a modification example 10 of the embodiment 1. As illustrated in FIG. 16, a film thickness L3 of the boundary insulating film 15 in the up-down direction is larger than a film thickness L4 of the upper insulating film 13 in the right-left direction.

According to the modification example 10, since the film thickness L4 of the upper insulating film 13 is small, improvement of the withstand voltage of the semiconductor device can be expected in the configuration that deterioration of the withstand voltage of the semiconductor device is concerned.

### Modification Example 11

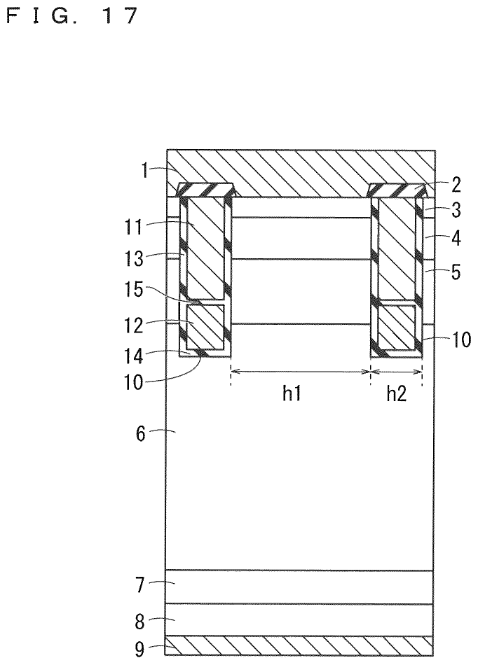

FIG. 17 is a cross-sectional view of a semiconductor device according to a modification example 11 of the embodiment 1. As illustrated in FIG. 17, a length h1 between the two-stage trenches 10 adjacent to each other is larger than a width h2 of the two-stage trench 10 in the right-left direction.

According to the modification example 11, since the length h1 between the two-stage trenches 10 adjacent to each other is increased, improvement of the withstand voltage of the semiconductor device can be expected in the configuration that electrical field concentration per unit trench increases and reduction of the withstand voltage is concerned.

### Modification Example 12

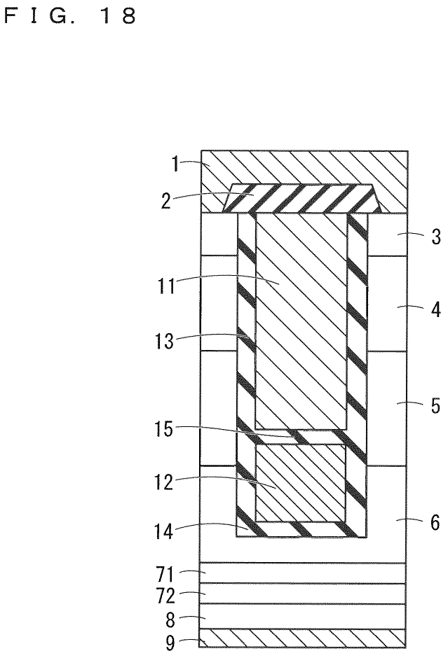

FIG. 18 is a cross-sectional view of a semiconductor device according to a modification example 12 of the embodiment 1. As illustrated in FIG. 18, the semiconductor device according to the modification example 12 includes a first buffer layer 71 and a second buffer layer 72.

According to the modification example 12, the plurality of buffer layers (the first buffer layer 71 and the second buffer layer 72) are included on a side of the lower surface of the semiconductor substrate. Since the electrical field on the side of the lower surface (a side of the collector electrode 9) gets low and the electrical field on the side of the upper surface (a side of the upper surface of the source layer 3) gets high, the withstand voltage of the semiconductor device is further improved.

### Modification Example 13

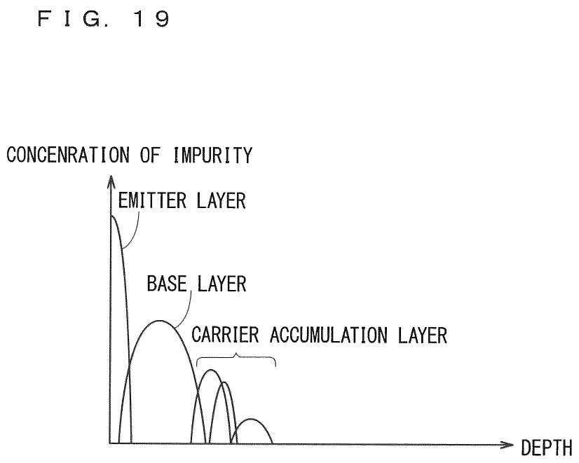

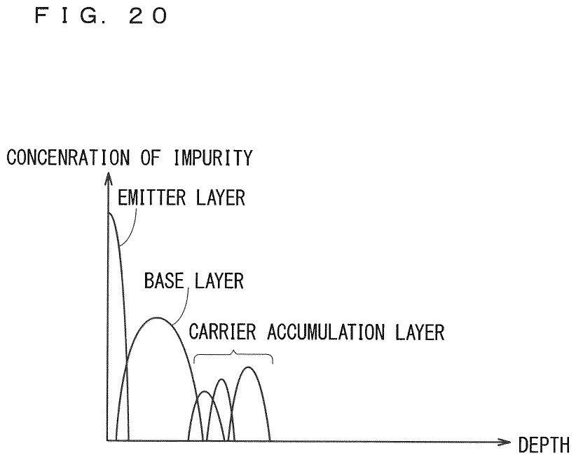

FIGS. 19 and 20 are diagrams illustrating an impurity concentration of each layer in a semiconductor device according to a modification example 13 of the embodiment 1. As illustrated in FIGS. 19 and 20, the semiconductor device according to the modification example 13 includes a plurality of carrier accumulation layers. That is to say, the carrier accumulation layer 5 illustrated in FIG. 1 includes the plurality of carrier accumulation layers. In the example in FIG. 19, the peak of the impurity concentration of each carrier accumulation layer gradually decreases from a side of the upper surface toward a side of the lower surface. In the example in FIG. 20, the peak of the impurity concentration of each carrier accumulation layer gradually increases from the side of the upper surface toward the side of the lower surface.

According to the modification example 13, applied is the configuration that the plurality of carrier accumulation layers are included and more carriers are accumulated; thus, the improvement of the withstand voltage of the semiconductor device can be expected.

As illustrated in FIG. 19, since the impurity concentration of the carrier accumulation layer on the side of the upper surface is higher than that of the carrier accumulation layer on the side of the lower surface, a carrier accumulation effect is increased, and ON voltage of the semiconductor device can be reduced.

As illustrated in FIG. 20, since the impurity concentration of the carrier accumulation layer on the side of the lower side is higher than that of the carrier accumulation layer on the side of the upper surface, overlap of the lower end of the upper electrode 11 in which the electrical field tends to be concentrated and the carrier accumulation layer having the high impurity concentration can be avoided, and the withstand voltage of the semiconductor device can be improved.

### Modification Example 14

In a semiconductor device according to a modification example 14, the semiconductor substrate includes wide bandgap semiconductor. Examples of the wide bandgap semiconductor include silicon carbide (SiC), gallium nitride (GaN), and gallium oxide (Ga₂O₃).

Electrical field strength of the wide bandgap semiconductor tends to be high compared with that of silicon (Si). According to the modification example 14, the electrical field reduction effect can be obtained with a larger degree. Thus, the withstand voltage of the semiconductor device can be improved.

### Modification Example 15

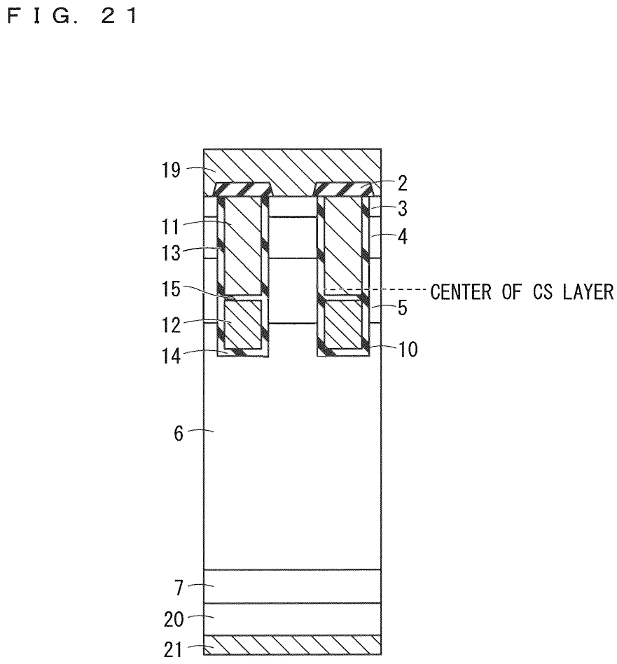

FIG. 21 is a cross-sectional view of a semiconductor device according to a modification example 15 of the embodiment 1. As illustrated in FIG. 21, the semiconductor device according to the modification example 15 is a metal oxide semiconductor field effect transistor (MOSFET) including a drain layer 20 provided to the side of the lower surface of the semiconductor substrate, a drain electrode 21 provided to a side of a lower surface of the drain layer 20, and a source electrode 19 provided to cover the interlayer insulating film 2 and the source layer 3.

According to the modification example 15, even when the semiconductor device is the MOSFET, the electrical field reduction effect similar to that in the semiconductor device (IGBT) according to the embodiment 1 can be obtained.

Since hole current flows in an operation of a parasitic body diode, the electrical field of the second high electrical field region can be reduced, although not as much as the case of the IGBT.

### Modification Example 16

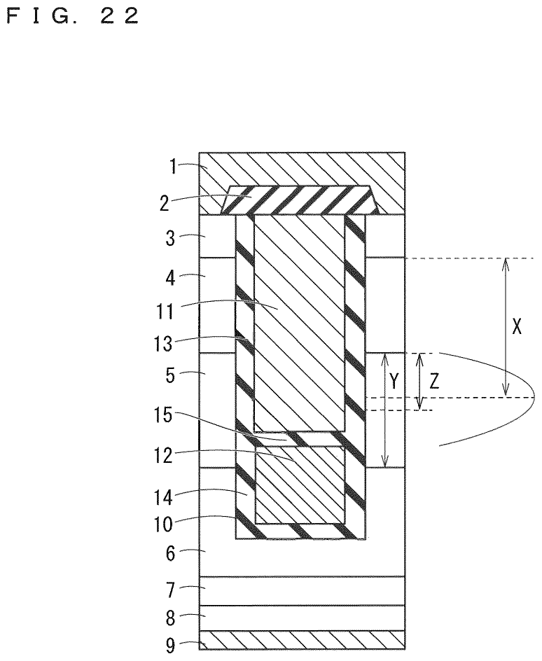

FIG. 22 is a cross-sectional view of a semiconductor device according to a modification example 16 of the embodiment 1. As illustrated in FIG. 22, a position X of the peak of the impurity concentration of the carrier accumulation layer 5 from the upper surface of the source layer 3 is located more upward than a center position Z of a length Y of the carrier accumulation layer 5 in the up-down direction. That is to say, the peak of the impurity concentration of the carrier accumulation layer 5 is located more upward than the center position of the carrier accumulation layer 5 in the up-down direction.

According to the modification example 16, since an accumulation region of the hole is located more upward than the third electrical field region, electrical field concentration of the third high electrical field region is reduced, and the withstand voltage of the semiconductor device can be improved.

### Modification Example 17

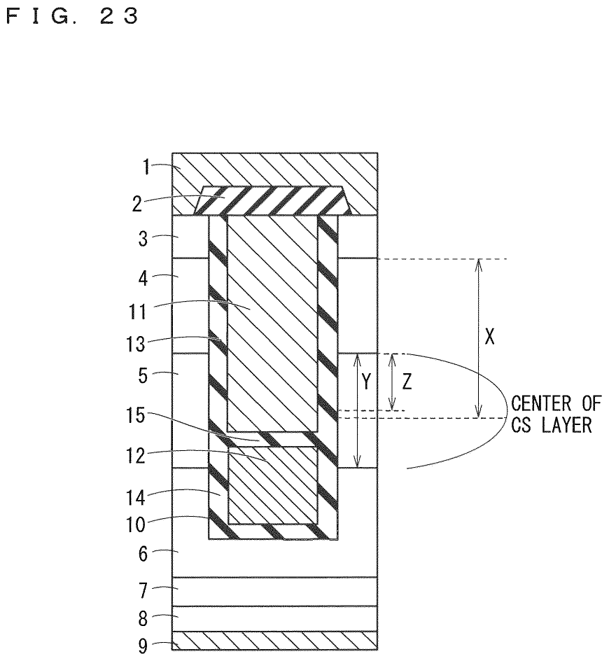

FIG. 23 is a cross-sectional view of a semiconductor device according to a modification example 17 of the embodiment 1. As illustrated in FIG. 23, the position X of the peak of the impurity concentration of the carrier accumulation layer 5 from the upper surface of the source layer 3 is located more downward than the center position Z of the length Y of the carrier accumulation layer 5 in the up-down direction. That is to say, the peak of the impurity concentration of the carrier accumulation layer 5 is located more downward than the center position of the carrier accumulation layer 5 in the up-down direction.

According to the modification example 17, the peak of the impurity concentration of the carrier accumulation layer 5 can be away from the interface between the base layer 4 and the carrier accumulation layer 5. Accordingly, electrical field concentration of the first high electrical field region is reduced, and the withstand voltage of the semiconductor device can be improved.

### Modification Example 18

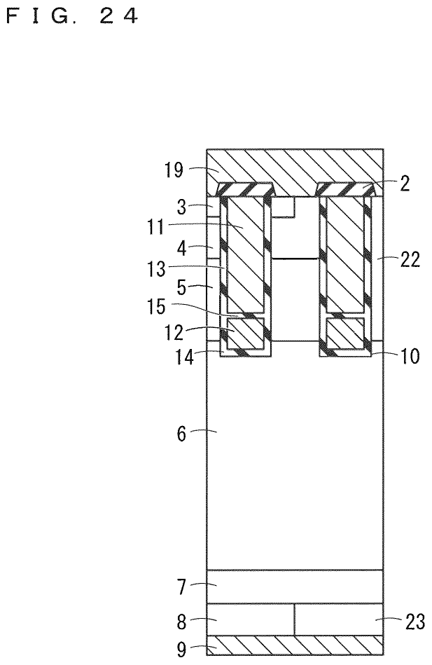

FIG. 24 is a cross-sectional view of a semiconductor device according to a modification example 18 of the embodiment 1. As illustrated in FIG. 24, the semiconductor device according to the modification example 18 is a reverse conducting IGBT (RC-IGBT) including an IGBT region including the collector layer 8 provided to the side of the lower surface of the semiconductor substrate and a diode region including a cathode layer 23 provided to the side of the lower surface of the semiconductor substrate, and an anode layer 22 provided to the side of the upper surface of the semiconductor substrate.

Influence of the second high electrical field region caused by the hole is particularly large in the IGBT in which the hole is used as the carrier. According to the modification example 18, the withstand voltage of the IGBT region can be further improved.

Although the electrical field concentration tends to occur in the boundary between the diode region and the IGBT region, such an electrical field concentration can be reduced in the RC-IGBT according to the modification example 18.

### Modification Example 19

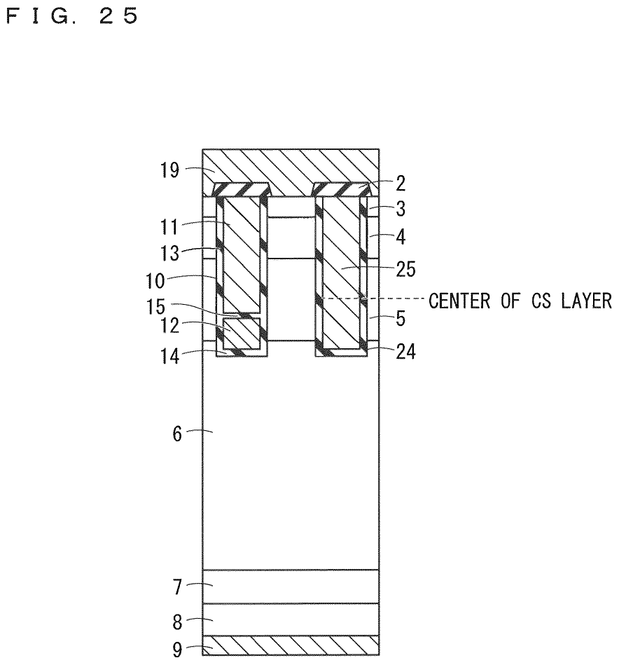

FIG. 25 is a cross-sectional view of a semiconductor device according to a modification example 19 of the embodiment 1. As illustrated in FIG. 25, the semiconductor device according to the modification example 19 includes a single trench 24. The single trench 24 includes one gate electrode 25 inside a trench provided to pass through the source layer 3 on the side of the upper surface of the semiconductor substrate, the base layer 4, and the carrier accumulation layer 5.

The semiconductor device according to the modification example 19 includes the two-stage trench 10 in addition to the single trench 24. The configuration of the two-stage trench 10 may be the configuration of the two-stage trench 10 described in the modification examples 1 to 11, 16, and 17. The configuration of the semiconductor device according to the modification example 19 may be the configuration of the semiconductor device according to the modification examples 12 to 15 and 18.

According to the modification example 19, since the single trench 24 with no third high electrical field region is included, reduction of the withstand voltage specific to the semiconductor device including the two-stage trench 10 can be suppressed.

### Modification Example 20

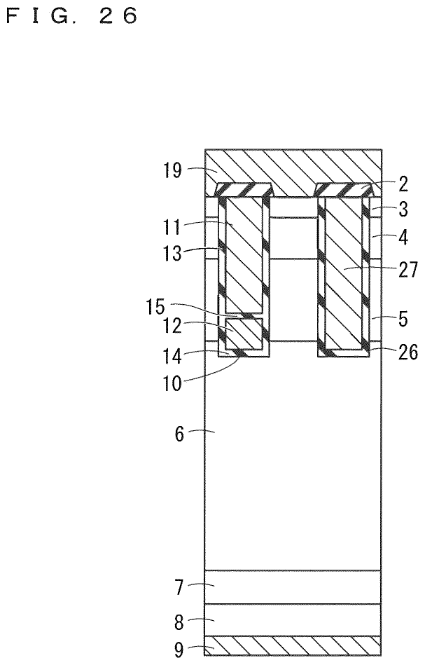

FIG. 26 is a cross-sectional view of a semiconductor device according to a modification example 20 of the embodiment 1. As illustrated in FIG. 26, the semiconductor device according to the modification example 20 includes a dummy trench 26. The dummy trench 26 includes one dummy electrode 27 inside the trench provided to pass through the source layer 3 on the side of the upper surface of the semiconductor substrate, the base layer 4, and the carrier accumulation layer 5. The dummy electrode 27 is electrically connected to the emitter electrode.

The semiconductor device according to the modification example 20 includes the two-stage trench 10 in addition to the dummy trench 26. The configuration of the two-stage trench 10 may be the configuration of the two-stage trench 10 described in the modification examples 1 to 11, 16, and 17. The configuration of the semiconductor device according to the modification example 20 may be the configuration of the semiconductor device according to the modification examples 12 to 15 and 18.

According to the modification example 20, since the dummy trench 26 is included the potential around the trench can be reduced. Thus, the electrical field can be reduced, and the withstand voltage of the semiconductor device can be improved. Since the number of trenches is not reduced, the electrical field concentration due to reduction of the number of trenches hardly occurs.

### Modification Example 21

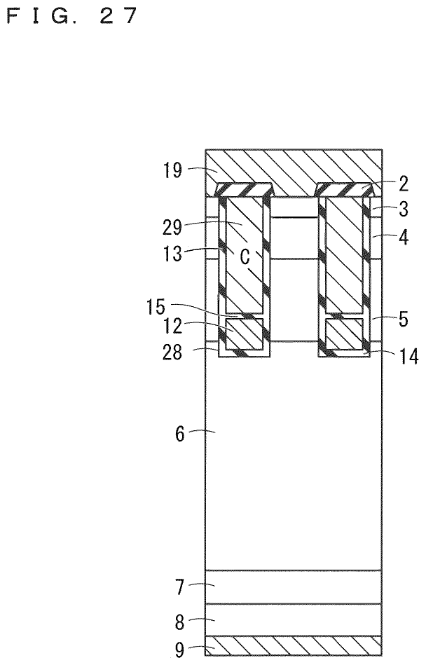

FIG. 27 is a cross-sectional view of a semiconductor device according to a modification example 21 of the embodiment 1. As illustrate in FIG. 27, the upper electrode 11 in the two-stage trench 28 is a control gate electrode electrically connected to control gate potential. The control gate potential is potential different from gate potential used for switching ON or OFF the semiconductor device. Since the carrier is taken off or implanted at an optional timing via the control electrode, switching loss of the semiconductor device can be reduced.

Although FIG. 27 illustrates the example of the case where the upper electrode 11 is the control gate electrode, the lower electrode 12 may be the control gate electrode. That is to say, it is sufficient that at least one of the upper electrode 11 and the lower electrode 12 is the control gate electrode.

The semiconductor device according to the modification example 21 includes the two-stage trench 10 with no control gate electrode. The configuration of the two-stage trench 10 may be the configuration of the two-stage trench 10 described in the modification examples 1 to 11, 16, and 17. The configuration of the semiconductor device according to the modification example 21 may be the configuration of the semiconductor device according to the modification examples 12 to 15 and 18.

According to the modification example 21, since the control electrode is included, the carrier can be appropriately discharged. Thus, the carrier concentration in the carrier accumulation layer 5 can get high, and is further effective in maintaining the withstand voltage in such a design.

### Embodiment 2

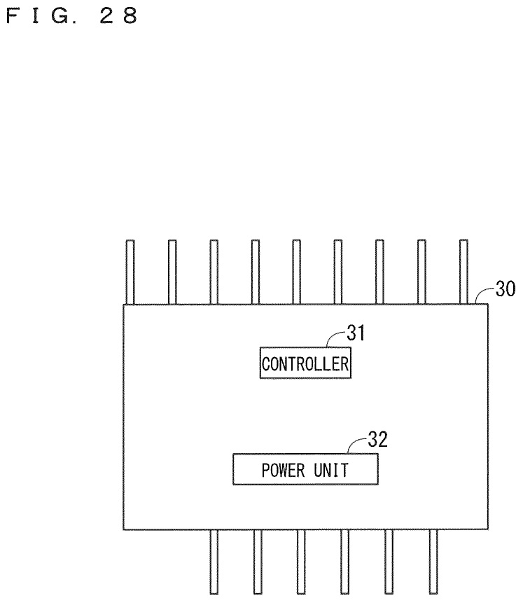

FIG. 28 is a plan view of a power module 30 according to an embodiment 2. As illustrated in FIG. 28, the power module 30 according to the embodiment 2 includes a controller 31 and a power unit 32.

The controller 31 corresponds to an integrated circuit (IC) and controls the power unit 32. Accordingly, the power module 30 including the controller 31 is also referred to as an intelligent power module.

The power unit 32 corresponds to the semiconductor device according to any one of the embodiment 1 and the modification examples 1 to 21.

The controller 31 and the power unit 32 are sealed with molding resin or gel.

According to the embodiment 2, since the semiconductor device according to any one of the embodiment 1 and the modification examples 1 to 21 is included as the power unit 32, the withstand voltage of the power module can be improved.

Each embodiment can be arbitrarily combined, or each embodiment can be appropriately varied or omitted within the scope of the present disclosure.

### Appendix

The aspects of the present disclosure are collectively described hereinafter as appendixes.

### Appendix 1

A semiconductor device, comprising:
a semiconductor substrate;
a base layer provided to a side of an upper surface of the semiconductor substrate;
at least one carrier accumulation layer provided below the base layer; and
at least one two-stage trench including an upper electrode and a lower electrode on an upper tier and a lower tier, respectively, inside a trench provided to the side of the upper surface of the semiconductor substrate to pass through the base layer and the carrier accumulation layer, wherein
a lower end of the upper electrode is located more upward than a lower end of the carrier accumulation layer and more downward than a center position of the carrier accumulation layer in an up-down direction.

### Appendix 2

The semiconductor device according to Appendix 1, wherein
a peak of an impurity concentration of the carrier accumulation layer is located more downward than an upper end of the carrier accumulation layer, and
the lower end of the upper electrode is located more downward than the peak of the impurity concentration of the carrier accumulation layer.

### Appendix 3

The semiconductor device according to Appendix 1 or 2, wherein
a length between the lower end of the carrier accumulation layer and a lower end of the two-stage trench is smaller than a length of the carrier accumulation layer in the up-down direction.

### Appendix 4

The semiconductor device according to any one of Appendixes 1 to 3, wherein
a length of the lower electrode in an up-down direction is smaller than a length of the upper electrode in an up-down direction.

### Appendix 5

The semiconductor device according to any one of Appendixes 1 to 4, wherein
a width of the upper electrode in a right-left direction is larger than a width of the lower electrode in a right-left direction.

### Appendix 6

The semiconductor device according to any one of Appendixes 1 to 5, wherein
the upper electrode includes a projection part on the lower end.

### Appendix 7

The semiconductor device according to any one of Appendixes 1 to 6, wherein
a length of the base layer in an up-down direction at an interface with the two-stage trench is smaller than a length of the base layer in the up-down direction at a center of a mesa part.

### Appendix 8

The semiconductor device according to any one of Appendixes 1 to 7, wherein
the two-stage trench includes a two-stage active trench in which the upper electrode and the lower electrode are electrically connected to a gate electrode.

### Appendix 9

The semiconductor device according to any one of Appendixes 1 to 8, wherein
the two-stage trench includes a two-stage dummy active trench in which the upper electrode is electrically connected to an emitter electrode and the lower electrode is electrically connected to a gate electrode.

### Appendix 10

The semiconductor device according to any one of Appendixes 1 to 9, wherein
the two-stage trench includes a two-stage active dummy trench in which the upper electrode is electrically connected to a gate electrode and the lower electrode is electrically connected to an emitter electrode.

### Appendix 11

The semiconductor device according to any one of Appendixes 1 to 10, wherein
the two-stage trench includes an upper insulating film covering the upper electrode and a boundary insulating film located between the upper electrode and the lower electrode, and
a film thickness of the boundary insulating film in an up-down direction is larger than a film thickness of the upper-stage insulating film in a right-left direction.

### Appendix 12

The semiconductor device according to any one of Appendixes 1 to 11, wherein
a length between the two-stage trenches adjacent to each other is larger than a width of the two-stage trench in a right-left direction.

### Appendix 13

The semiconductor device according to any one of Appendixes 1 to 12, further comprising
a plurality of buffer layers on a side of the lower surface of the semiconductor substrate.

### Appendix 14

The semiconductor device according to any one of Appendixes 1 to 13, wherein
the semiconductor device is an insulated gate bipolar transistor (IGBT) including collector layer provided to the side of the lower surface of the semiconductor substrate.

### Appendix 15

The semiconductor device according to any one of Appendixes 1 to 14, comprising
a plurality of carrier accumulation layers.

### Appendix 16

The semiconductor device according to any one of Appendixes 1 to 15, wherein
the semiconductor substrate includes wide bandgap semiconductor.

### Appendix 17

The semiconductor device according to any one of Appendixes 1 to 16, wherein
the semiconductor device is a metal oxide semiconductor field effect transistor (MOSFET) including a drain layer provided to the side of the lower surface of the semiconductor substrate.

### Appendix 18

The semiconductor device according to any one of Appendixes 1 to 17, wherein
a peak of the impurity concentration of the carrier accumulation layer is located more upward than a center position of the carrier accumulation layer in the up-down direction.

### Appendix 19

The semiconductor device according to any one of Appendixes 1 to 17, wherein
a peak of the impurity concentration of the carrier accumulation layer is located more downward than a center position of the carrier accumulation layer in the up-down direction.

### Appendix 20

The semiconductor device according to any one of Appendixes 1 to 19, wherein
the semiconductor device is a reverse conducting IGBT (RC-IGBT) including an IGBT region including a collector layer provided to the side of the lower surface of the semiconductor substrate and a diode region including a cathode layer provided to the side of the lower surface of the semiconductor substrate.

### Appendix 21

The semiconductor device according to any one of Appendixes 1 to 20, further comprising
at least one single trench including one electrode inside a trench provided to the side of the upper surface of the semiconductor substrate to pass through the base layer and the carrier accumulation layer.

### Appendix 22

The semiconductor device according to Appendix 21, wherein
the single trench includes a dummy trench in which the electrode is electrically connected to an emitter electrode.

### Appendix 23

The semiconductor device according to any one of Appendixes 1 to 22, wherein
at least one of the upper electrode and the lower electrode is a control gate electrode electrically connected to control gate potential.

### Appendix 24

A power module, comprising
the semiconductor device according to any one of Appendixes 1 to 23.

### Appendix 25

The power module according to Appendix 24, further comprising
molding resin or gel.

### Appendix 26

The power module according to Appendix 24 or 25, further comprising
an integrated circuit (IC) chip.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate;
a base layer provided to a side of an upper surface of the semiconductor substrate;
at least one carrier accumulation layer provided below the base layer; and
at least one two-stage trench including an upper electrode and a lower electrode on an upper tier and a lower tier, respectively, inside a trench provided to the side of the upper surface of the semiconductor substrate to pass through the base layer and the carrier accumulation layer, wherein
a lower end of the upper electrode is located more upward than a lower end of the carrier accumulation layer and more downward than a center position of the carrier accumulation layer in an up-down direction.

2. The semiconductor device according to claim 1, wherein
a peak of an impurity concentration of the carrier accumulation layer is located more downward than an upper end of the carrier accumulation layer, and
the lower end of the upper electrode is located more downward than the peak of the impurity concentration of the carrier accumulation layer.

3. The semiconductor device according to claim 1, wherein
a length between the lower end of the carrier accumulation layer and a lower end of the two-stage trench is smaller than a length of the carrier accumulation layer in the up-down direction.

4. The semiconductor device according to claim 1, wherein
a length of the lower electrode in an up-down direction is smaller than a length of the upper electrode in an up-down direction.

5. The semiconductor device according to claim 1, wherein
a width of the upper electrode in a right-left direction is larger than a width of the lower electrode in a right-left direction.

6. The semiconductor device according to claim 1, wherein
the upper electrode includes a projection part on the lower end.

7. The semiconductor device according to claim 1, wherein
a length of the base layer in an up-down direction at an interface with the two-stage trench is smaller than a length of the base layer in the up-down direction at a center of a mesa part.

8. The semiconductor device according to claim 1, wherein
the two-stage trench includes a two-stage active trench in which the upper electrode and the lower electrode are electrically connected to a gate electrode.

9. The semiconductor device according to claim 1, wherein
the two-stage trench includes a two-stage dummy active trench in which the upper electrode is electrically connected to an emitter electrode and the lower electrode is electrically connected to a gate electrode.

10. The semiconductor device according to claim 1, wherein
the two-stage trench includes a two-stage active dummy trench in which the upper electrode is electrically connected to a gate electrode and the lower electrode is electrically connected to an emitter electrode.

11. The semiconductor device according to claim 1, wherein
the two-stage trench includes an upper insulating film covering the upper electrode and a boundary insulating film located between the upper electrode and the lower electrode, and
a film thickness of the boundary insulating film in an up-down direction is larger than a film thickness of the upper-stage insulating film in a right-left direction.

12. The semiconductor device according to claim 1, wherein
a length between the two-stage trenches adjacent to each other is larger than a width of the two-stage trench in a right-left direction.

13. The semiconductor device according to claim 1, further comprising
a plurality of buffer layers on a side of the lower surface of the semiconductor substrate.

14. The semiconductor device according to claim 1, wherein
the semiconductor device is an insulated gate bipolar transistor (IGBT) including a collector layer provided to the side of the lower surface of the semiconductor substrate.

15. The semiconductor device according to claim 1, comprising
a plurality of carrier accumulation layers.

16. The semiconductor device according to claim 1, wherein
the semiconductor substrate includes wide bandgap semiconductor.

17. The semiconductor device according to claim 1, wherein
the semiconductor device is a metal oxide semiconductor field effect transistor (MOSFET) including a drain layer provided to the side of the lower surface of the semiconductor substrate.

18. The semiconductor device according to claim 1, wherein
a peak of the impurity concentration of the carrier accumulation layer is located more upward than a center position of the carrier accumulation layer in the up-down direction.

19. The semiconductor device according to claim 1, wherein
a peak of the impurity concentration of the carrier accumulation layer is located more downward than a center position of the carrier accumulation layer in the up-down direction.

20. The semiconductor device according to claim 1, wherein
the semiconductor device is a reverse conducting IGBT (RC-IGBT) including an IGBT region including a collector layer provided to the side of the lower surface of the semiconductor substrate and a diode region including a cathode layer provided to the side of the lower surface of the semiconductor substrate.

21. The semiconductor device according to claim 1, further comprising
at least one single trench including one electrode inside a trench provided to the side of the upper surface of the semiconductor substrate to pass through the base layer and the carrier accumulation layer.

22. The semiconductor device according to claim 21, wherein
the single trench includes a dummy trench in which the electrode is electrically connected to an emitter electrode.

23. The semiconductor device according to claim 1, wherein
at least one of the upper electrode and the lower electrode is a control gate electrode electrically connected to control gate potential.

24. A power module, comprising
the semiconductor device according to claim 1.

25. The power module according to claim 24, further comprising
molding resin or gel.

26. The power module according to claim 25, further comprising
an integrated circuit (IC) chip.
